(19) United States
(12) Patent Application Publication
(10) Pub. No.: US 2018/0315860 A1
(43) Pub. Date: Nov. 1, 2018

(54) VERTICAL THIN-FILM TRANSISTOR WITH MULTIPLE-JUNCTION CHANNEL

(71) Applicant: The Hong Kong University of Science and Technology, Kowloon (HK)

(72) Inventors: Lei Lu, Kowloon (HK); Zhi He Xia, Kowloon (HK); Jia Peng Li, Kowloon (HK); Man Wong, New Territories (HK); Hoi Sing Kwok, Kowloon (HK)

(21) Appl. No.: 15/581,322

(22) Filed: Apr. 28, 2017

(51) Int. Cl. H01L 29/786; H01L 29/49; H01L 29/66; H01L 21/477; H01L 21/768

(52) U.S. Cl. CPC H01L 29/78609; H01L 29/7869; H01L 29/78642; H01L 29/78696; H01L 29/78618; H01L 21/76895; H01L 29/4908; H01L 29/66969; H01L 21/477; H01L 21/76805; H01L 29/78606

(57) ABSTRACT

Aspects describe a vertical metal-oxide thin-film transistor with multiple-junction channel and a method to fabricate the same. In one example, the vertical transistor comprises a substrate, an interconnecting electrode and source and drain electrodes separated by a spacer. The vertical transistor also includes a metal oxide active layer formed over the interconnecting electrode and the source and drain electrodes and adjacent to the interconnecting electrode, the spacer, and the source and drain electrodes. Further, the vertical transistor includes a gate stack adjacent to the metal oxide active layer and a multiple-junction channel region provided within the metal oxide active layer adjacent to the gate stack.

### TECHNICAL FIELD

The following description relates generally to vertical thin-film transistors with multiple-junction channel and a method for fabricating the same.

### BACKGROUND

A thin-film transistor (TFT) consists of a channel region located between source and drain (S/D) regions. The resistance of the channel is modulated by the voltage on the gate electrode, while the resistance of the S/D regions is not modulated. For a metal-oxide (MO) TFT, Schottky barriers are formed at the junctions where the S/D conductors contact the metal oxide layer. The resistance associated with such a junction is high, resulting in lowering of the on-state current, as compared with its high-end silicon counterpart, low temperature ploy-Si (LTPS) TFT. Although the MO TFT has a lower power consumption due to the lower off-state current, the MO TFT has a relatively lower mobility, thus poorer driving capability. Compared with a planar TFT structure, a vertical TFT structure can provide a much higher driving current due to a higher width/length ratio, often at a cost of an increasing off-state current.

The above-described deficiencies of conventional MO TFT devices are merely intended to provide an overview of some of problems of current technology, and are not intended to be exhaustive. Other problems with the state of the art, and corresponding benefits of some of the various non-limiting embodiments described herein, may become further apparent upon review of the following detailed description.

### BRIEF DESCRIPTION OF THE DRAWINGS

Non-limiting and non-exhaustive embodiments of the subject disclosure are described with reference to the following figures, wherein like reference numerals refer to like parts throughout the various views unless otherwise specified.

FIG. 1 illustrates a layout diagram of a vertical thin-film transistor with multiple-junction channel in accordance with one or more embodiments described herein.

FIG. 2A illustrates the layout of the vertical thin-film transistor along line A-A′ of FIG. 1 in accordance with one or more embodiments described herein.

FIG. 2B illustrates the layout of FIG. 1 demonstrating a flow of current through the multiple-junctions in accordance with one or more embodiments described herein.

FIG. 3 illustrates the layout of the vertical thin-film transistor along line B-B′ of FIG. 1 in accordance with one or more embodiments described herein.

FIG. 4 illustrates the layout of the vertical thin-film transistor along line C-C′ of FIG. 1 in accordance with one or more embodiments described herein.

FIG. 5A illustrates a top view of formation of a metal layer over a substrate during fabrication of a vertical bottom-gate thin film transistor in accordance with one or more embodiments described herein.

FIG. 5B illustrates a side view of the transistor of FIG. 5A in accordance with one or more embodiments described herein.

FIG. 6A illustrates a top view of formation of a stack structure during fabrication of a vertical bottom-gate thin film transistor in accordance with one or more embodiments described herein.

FIG. 6B illustrates a side view of the transistor of FIG. 6A in accordance with one or more embodiments described herein.

FIG. 7A illustrates a top view of formation of a gate stack during fabrication of a vertical bottom-gate thin film transistor in accordance with one or more embodiments described herein.

FIG. 7B illustrates a side view of the transistor of FIG. 7A in accordance with one or more embodiments described herein.

FIG. 8A illustrates a top view of formation of an extra passivation layer and contact holes opening during fabrication of a vertical bottom-gate thin film transistor in accordance with one or more embodiments described herein.

FIG. 8B illustrates a side view of the transistor of FIG. 8A in accordance with one or more embodiments described herein.

FIG. 9A illustrates a top view of electrode deposition during fabrication of a vertical bottom-gate thin film transistor in accordance with one or more embodiments described herein.

FIG. 9B illustrates a side view of the transistor of FIG. 9A in accordance with one or more embodiments described herein.

FIG. 10 illustrates a layout diagram of another vertical thin-film transistor with multiple-junction channel in accordance with one or more embodiments described herein.

FIG. 11 illustrates the layout of the vertical thin-film transistor along line A-A′ of FIG. 10 in accordance with one or more embodiments described herein.

FIG. 12 illustrates the layout of the vertical thin-film transistor along line B-B′ of FIG. 10 in accordance with one or more embodiments described herein.

FIG. 13 illustrates the layout of the vertical thin-film transistor along line C-C′ of FIG. 10 in accordance with one or more embodiments described herein.

FIG. 14 illustrates an example, non-limiting method for fabricating a thin film transistor in accordance with one or more embodiments described herein.

FIG. 15 illustrates an example, non-limiting method for forming a vertical thin-film transistor with multiple-junction channel in accordance with one or more embodiments described herein.

FIG. 16 illustrates an example, non-limiting method for forming another vertical thin-film transistor with multiple-junction channel in accordance with one or more embodiments described herein.

FIG. 17 illustrates an example, non-limiting method for fabricating a vertical thin film transistor in accordance with one or more embodiments described herein.

### DETAILED DESCRIPTION

Various aspects or features of this disclosure are described with reference to the drawings, wherein like reference numerals are used to refer to like elements throughout. In this specification, for purposes of explanation, numerous specific details are set forth in order to provide a thorough understanding of the subject disclosure. It should be understood, however, that certain aspects of this disclosure may be practiced without these specific details, or with other methods, components, materials, and so on. In other instances, well-known structures and devices are shown in block diagram form to facilitate describing the subject disclosure.

By way of introduction, the subject matter disclosed herein relates to vertical thin-film transistors (TFTs) with a multiple-junction channel and a method of fabricating the same. In some embodiments, the electrode connecting multiple junctions can be beneath source/drain electrodes. In some embodiments, the electrode connecting multiple-junctions can be above the source/drain electrodes (S/D electrodes). In some embodiments, the vertical TFT can include a gas permeable gate stack. Further, in some embodiments, formation of the vertical TFT can include a simultaneous patterning process (or a concurrent patterning process) for both a gate stack and an active layer.

An aspect relates to a transistor structure that can include a layered stack structure formed on a substrate. The transistor structure can also include an active layer formed over and adjacent to the layered stack structure. The active layer can include metal-oxide. Further, the transistor structure can include a gate stack adjacent to the active layer. The gate stack can include a gate dielectric adjacent to the active layer and a gate electrode adjacent to the gate dielectric. Multiple junctions can be provided within the active layer adjacent to interfaces between the interconnecting electrode, S/D electrode, and the active layer. Further, the multiple junctions within the active layer can be symmetric, resulting in a symmetric source and drain. According to some implementations, the active layer and the gate stack can be formed with a single mask during a concurrent patterning process.

In an implementation, the layered stack structure can include an interconnecting electrode deposited on the substrate, a spacer deposited on the interconnecting electrode, and a source electrode and a drain electrode deposited on the spacer. Further to this implementation, the multiple-junction channel region can be provided within the active layer adjacent to interfaces between the interconnecting electrode, the source electrode, the drain electrode, and the active layer.

In an alternative implementation the layered stack structure can include a source electrode and a drain electrode deposited on the substrate, a spacer deposited on the source electrode and the drain electrode, and an interconnecting electrode deposited on the spacer. Further to this implementation, the multiple-junction channel region can be provided within the active layer adjacent to interfaces between the interconnecting electrode, the source electrode, the drain electrode, and the active layer.

In an example, the gate stack can include a gas permeable layer. Further to this example, the gas permeable layer can include at least one of silicon oxide, silicon oxynitride, aluminum-zinc oxide, indium-zinc oxide, or indium-tin oxide. With the gas permeable layers of the gate stack, a conductivity of a metal-oxide channel can be suppressed by thermal oxidation, which can lower the off-state current.

The transistor structure, according to an example, can also include a passivation layer formed over and adjacent to the layered stack structure. Further, the transistor structure can include contact holes formed within the passivation layer. In addition, electrodes can be formed over the passivation layer and within the contact holes.

According to another aspect can be a method that includes forming a stack structure on a substrate. The method can also include forming an active layer over and adjacent to the stack structure. The active layer can comprise metal-oxide. Further, the method can include forming a gate stack adjacent to the active layer. Forming the active layer and the forming the gate stack can comprise using one mask for the active layer and the gate stack. According to some implementations, the method can include employing an oxidizing annealing to suppress a conductivity of a metal oxide channel.

In an example, forming the stack structure can include forming a bottom electrode layer on the substrate. Forming the stack structure can also include depositing a spacer on the bottom electrode layer and depositing an upper electrode layer on the spacer. Further, forming the stack structure can include patterning the bottom electrode layer, the spacer, and the upper electrode layer into the stack structure. According to some implementations, the method can also include forming the gate stack with a permeable layer. Further to this implementation, the permeable layer can include at least one of silicon oxide, silicon oxynitride, aluminum-zinc oxide, indium-zinc oxide, or indium-tin oxide.

In some examples, the method can include forming a passivation layer over and adjacent to the stack structure. Further, the method can include forming contact holes through the passivation layer and forming electrodes over the passivation layer and within the contact holes.

According to an example, forming the active layer and forming the gate stack can include patterning the active layer and the gate stack. Further to this example, patterning the active layer and the gate stack can include performing a single photolithography step.

Another aspect relates to a vertical transistor that can include a substrate. The vertical transistor can also include a source electrode and a drain electrode separated from an interconnecting electrode by a spacer, the source electrode and the drain electrode can be formed over the substrate. Further, the vertical transistor can include a metal oxide active layer formed over the interconnecting electrode, and adjacent to the interconnecting electrode, the spacer, the source electrode, and the drain electrode. Also included can be a gate stack adjacent to the metal oxide active layer and a multiple-junction channel region provided within the metal oxide active layer adjacent to the gate stack. Multiple junctions can be provided within the active layer adjacent to interfaces between the interconnecting electrode, the source electrode, the drain electrode, and the active layer. Further, the multiple junctions within the active layer can be symmetric, resulting in a symmetric source and drain.

In an example, the gate stack can include a gate dielectric adjacent to the metal oxide active layer and a gate electrode adjacent to the gate dielectric. In another example, the metal oxide active layer can be patterned with the gate stack. According to another example, the gate stack can comprise a gas permeable layer. Further to this example, the gas permeable layer can comprise at least one of silicon oxide, silicon oxynitride, aluminum-zinc oxide, indium-zinc oxide, and indium-tin oxide.

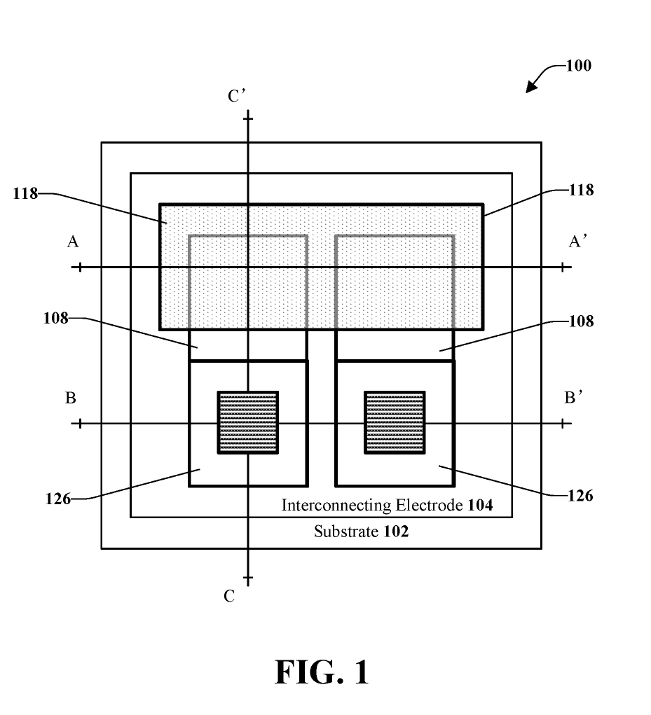

With reference initially to FIG. 1 illustrated is a layout diagram of a vertical thin-film transistor with multiple-junction channel in accordance with one or more embodiments described herein. Due to its electrical and optical properties, MOTFTs can be utilized for constructing the backplane of next-generation flat-panel display (FPD). Compared with its high-end silicon counterpart, namely a low temperature poly-Si (LTPS) TFT, the MO TFT exhibits much lower off-state current and, thus, lower power consumption. However, the MO TFT has relatively lower mobility and, thus, poorer driving capability. On the other hand, compared with the planar TFT structure, a vertical TFT structure can provide much higher driving current due to the higher width/length ratio, often at the cost of an increasing off-state current. The vertical MO TFT with multiple-junction channel provided herein can combine the merits of MO material and vertical TFT structure to build a vertical MO TFT, which can provide larger driving current and maintain a low off-state current concurrently.

The vertical TFT 100 can include a substrate 102 and an interconnecting electrode 104 formed on the substrate 102. According to some implementations, the interconnecting electrode 104 can be deposited and patterned on the substrate 102. Material used for the substrate 102 can vary. In an aspect, the substrate 102 can include an oxidized silicon wafer. In another aspect, the substrate 102 can include a transparent material (e.g., glass). In yet another aspect, the substrate 102 can include a flexible material (e.g., polymeric substrate). According to another aspect, the substrate 102 can include silicon dioxide. The interconnecting electrode 104 can be formed of conducting material to form a bottom metal source/drain electrode on the substrate.

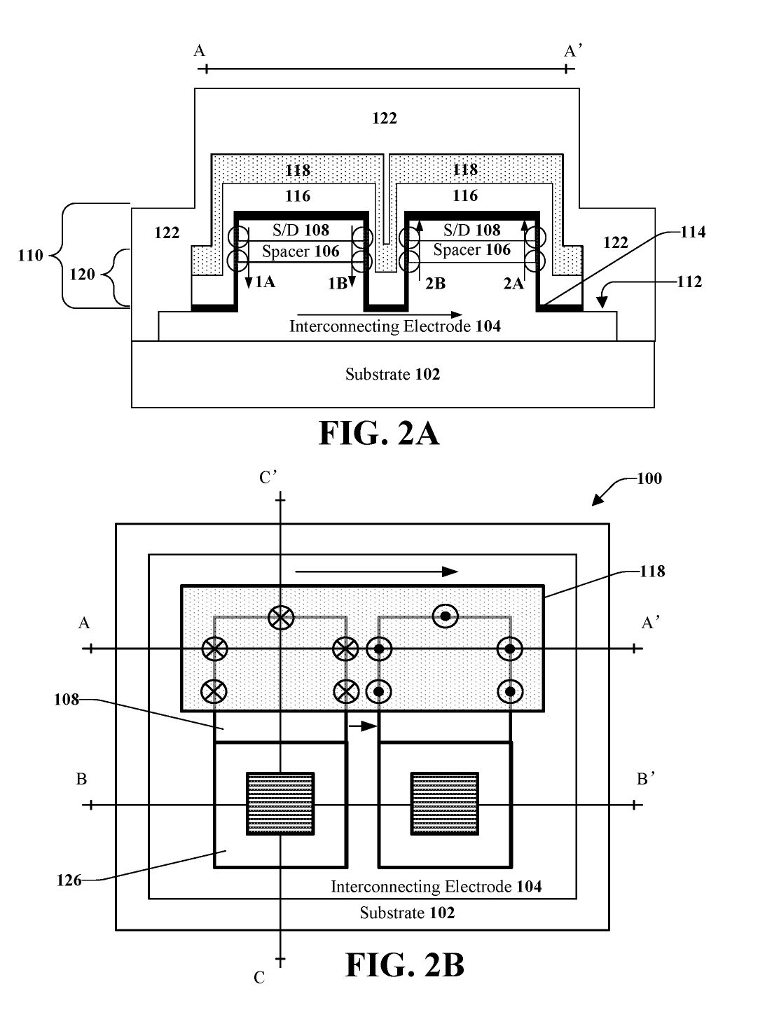

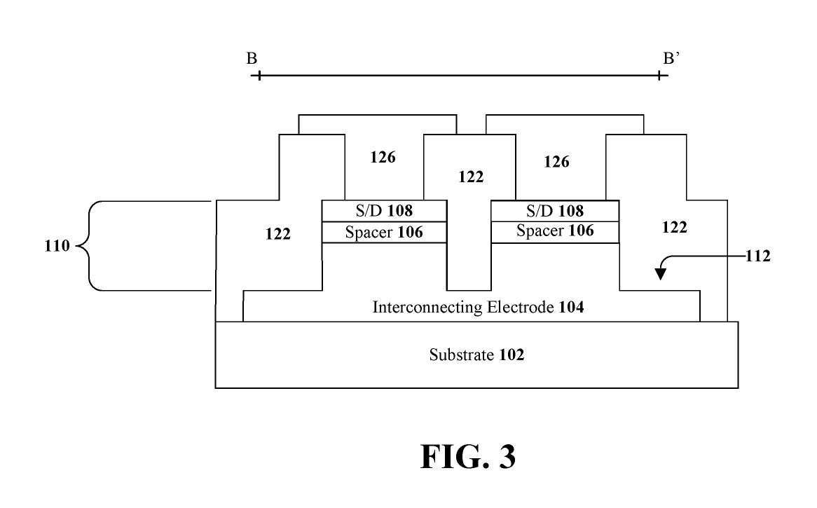

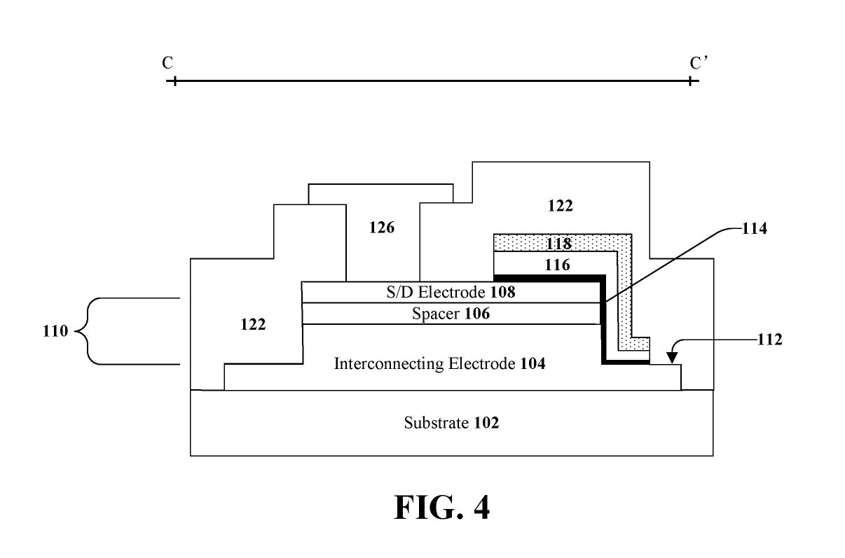

Reference is also now made to FIG. 2A, which illustrates the layout of the vertical thin-film transistor along line A-A′ of FIG. 1 in accordance with one or more embodiments described herein. With reference also to FIG. 3, which illustrates the layout of the vertical thin-film transistor along line B-B′ of FIG. 1 in accordance with one or more embodiments described herein. Reference is also made to FIG. 4, which illustrates the layout of the vertical thin-film transistor along line C-C′ of FIG. 1 in accordance with one or more embodiments described herein. Repetitive description of like elements employed in other embodiments described herein is omitted for sake of brevity.

On the interconnecting electrode 104, a spacer 106 of isolating material can be deposited to form an isolating layer. On the spacer 106, an S/D electrode 108 (e.g., a source electrode and a drain electrode) can be deposited. The S/D electrode 108 can be formed of conducting material to form an upper metal S/D electrode.

The interconnecting electrode 104, the spacer 106, and the S/D electrode 108 can be patterned to form a stack structure 110. The formation of the stack structure 110 can create a step area 112 that can be formed by at least a portion of the interconnecting electrode 104. For example, a first portion of the interconnecting electrode 104 can comprise a portion of the stack structure 110 and a second portion of the interconnecting electrode 104 can comprise the step area 112. The step area 112 can protrude horizontally away from the stack structure 110.

An active layer 114 can be formed over and adjacent to the stack structure 110. For example, the active layer 114 can be formed horizontally over a portion of the S/D electrode 108. Further, the active layer 114 can be formed vertically along a side of the stack structure 110 (e.g., the S/D electrode 108, the spacer 106, and the interconnecting electrode 104). Additionally, the active layer 114 can be formed horizontally along the portion of the interconnecting electrode 104 that comprises the step area 112. The active layer 114 might not completely cover the step area 112 as illustrated in FIG. 2A and FIG. 4. According to an aspect, the active layer 114 can include metal oxide (MO).

As illustrated by the circled areas in FIG. 2, the multiple-junctions are provided within the active layer adjacent to interfaces between the interconnecting electrode, the source electrode, and the drain electrode, and the active layer. The outside circles (indicated at 1A or 2A) of the junctions are parallel (e.g., equal) to the inside circles (indicated at 1B or 2B). As indicated by the arrow, the current passes the junction areas denoted by 1A and 1B in parallel first and then the current goes through the interconnecting electrode. Next, the current passes the junctions areas denoted by 2B and 2A in parallel.

In further detail, FIG. 2B illustrates the layout of FIG. 1 demonstrating a flow of current through the multiple-junctions in accordance with one or more embodiments described herein. As indicated by the arrows, the current passes the junction areas denoted by the circles having an “X” therein (e.g., 1A and 1B of FIG. 2A) and then go though the interconnecting electrode. Thereafter, the current passes the junction areas denoted by the circles having a dot therein (e.g., 2A and 2B of FIG. 2A).

With continuing reference to FIG. 2A, the active layer 114 can include a metal-oxide semiconductor material, such as but not limited to: zinc oxide, zinc oxynitride, tin oxide, indium oxide, gallium oxide, copper oxide, uranium oxide, bismuth oxide, indium-zinc oxide, tin-zinc oxide, aluminum-zinc oxide, aluminum-tin oxide, indium-tin oxide, indium-gallium-zinc oxide, indium-tin-zinc oxide, aluminum-tin-zinc oxide, aluminum-indium-tin-zinc oxide, indium-gallium-tin-zinc oxide, zinc sulphide, barium titanate, strontium titanate, and lithium niobate.

A thickness of the metal-oxide active layer can vary. In an aspect, the thickness of the active layer ranges from about 10 nm to about 1000 nm. In another aspect, the thickness of the active layer ranges from about 20 nm to about 800 nm. In another aspect, the thickness of the active layer ranges from about 50 nm to about 500 nm. In yet another aspect, the thickness of the active layer ranges from about 10 nm to about 100 nm.

Formed on the active layer 114 can be a gate dielectric 116. The gate dielectric 116 can be formed adjacent the active layer 114 and can follow a contour of the active layer 114. According to an aspect, the gate dielectric 116 can comprise a gate insulator (GI). A gate electrode layer 118 can be formed adjacent the gate dielectric 116 and can follow a contour of the gate dielectric. A gate stack 120 can comprise the gate dielectric 116 and the gate electrode layer 118. Multiple junctions can be provided within the active layer adjacent to interfaces between the interconnecting electrode, S/D electrode, and the active layer (e.g., illustrated by the circled areas in FIG. 2A). Further, the multiple junctions within the active layer can be symmetric resulting in a symmetric source and drain.

A passivation layer 122 can be introduced to protect the device (e.g., the vertical thin-film transistor 100). For example, the passivation layer 122 can serve to protect a source region, a drain region, and the channel region provided within the active layer 114. Openings or contact holes 124 can be formed within the passivation layer 122. Further, electrodes 126 can be formed over the passivation layer 122 and within the contact holes 124.

The gate dielectric and spacer comprise at least one of: silicon oxide, silicon nitride, silicon oxynitride, aluminum oxide, hafnium dioxide, and zirconium dioxide. The thickness of gate dielectric and spacer can vary. In an aspect, the thickness of the gate dielectric and spacer ranges from about 10 nm to about 1000 nm. In another aspect, the thickness of the gate dielectric and spacer ranges from about 20 nm to about 800 nm. In another aspect, the thickness of the gate dielectric and spacer ranges from about 50 nm to about 500 nm. In yet another aspect, the thickness of the gate dielectric and spacer ranges from about 100 nm to about 300 nm.

The interconnecting electrode and the S/D electrode can comprise at least one of: indium-tin oxide, indium-zinc oxide, aluminum-zinc oxide, titanium, aluminum molybdenum, copper, silver, gold, nickel, tungsten, chromium, hafnium, platinum, iron and their alloys. The thickness of the interconnecting electrode and the S/D electrode can vary. In an aspect, the thickness of the electrode ranges from about 100 nm to about 5000 nm. In another aspect, the thickness of the electrode ranges from about 200 nm to about 3000 nm. In another aspect, the thickness of the electrode ranges from about 300 nm to about 1000 nm. In yet another aspect, the thickness of the electrode ranges from about 200 nm to about 600 nm

As illustrated by the vertical TFT with multiple-junction channel as discussed herein, the multiple-junction channel can provide a low off-state current. Compared with planar TFT, vertical TFTs can have higher driving current, since the channel length can be smaller than the limitation of photolithography. However, in conventional vertical TFT, the junctions between source/drain and channel regions are not enough to suppress the off-state current, resulting in large off-state current and degrading power consumption performance. Further, the source and drain junctions are often non-symmetric, causing non-symmetric off-state current, which can be unfavorable for circuit design. The various aspects disclosed herein provide techniques to fabricate a vertical TFT with multiple-junction channel. The vertical TFT disclosed herein not only reduces the off-state current but can also provide symmetric source and drain junctions. Furthermore, the MO active layer can be patterned together with the gate stack, saving at least one photolithography step. Finally, the gate stack can include gas permeable layers, so that the thermal oxidization can further suppress the conductivity of the MO channel, thus lowering the off-state current.

MO TFTs are projected to replace silicon-based TFTs, thus, the disclosed aspects can benefit any devices that gainfully employ TFTs. These devices include all modern, high information-content, electronic flat-panel displays. Further, considering the high driving current of vertical MO TFT, the disclosed vertical transistor can be utilized for active-matrix organic light-emitting diode (AMOLED) displays, as an example.

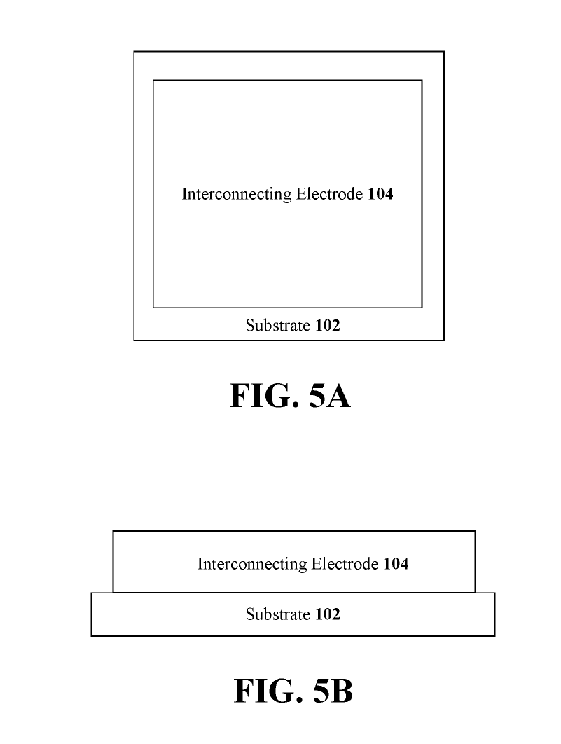

With reference now to FIGS. 5 through 9, detailed examples of a schematic process for fabrication of a vertical metal-oxide thin film transistor will be described. FIG. 5A illustrates a top view of formation of a metal layer over a substrate during fabrication of a vertical bottom-gate thin film transistor in accordance with one or more embodiments described herein. FIG. 5B illustrates a side view of the transistor of FIG. 5A in accordance with one or more embodiments described herein. Repetitive description of like elements employed in other embodiments described herein is omitted for sake of brevity.

On a substrate 102 an interconnecting electrode 104 can be formed. For example, the interconnecting electrode 104 can be deposited and patterned. Materials used for the substrate 102 can include, but is not limited to, an oxidized silicon wafer, a transparent material (e.g., glass), a flexible material (e.g., polymeric substrate), silicon dioxide, and so on. Further, material used for the interconnecting electrode 104 can include a conducting material. The interconnecting electrode 104 can form a bottom metal layer, which can be a first electrode in the transistor. As illustrated in FIG. 5A and FIG. 5B, the interconnecting electrode 104 might not extend the full length and the full width of the substrate 102. Therefore, as illustrated in the top view of FIG. 5B, a perimeter of the substrate 102 can extend beyond the interconnecting electrode 104.

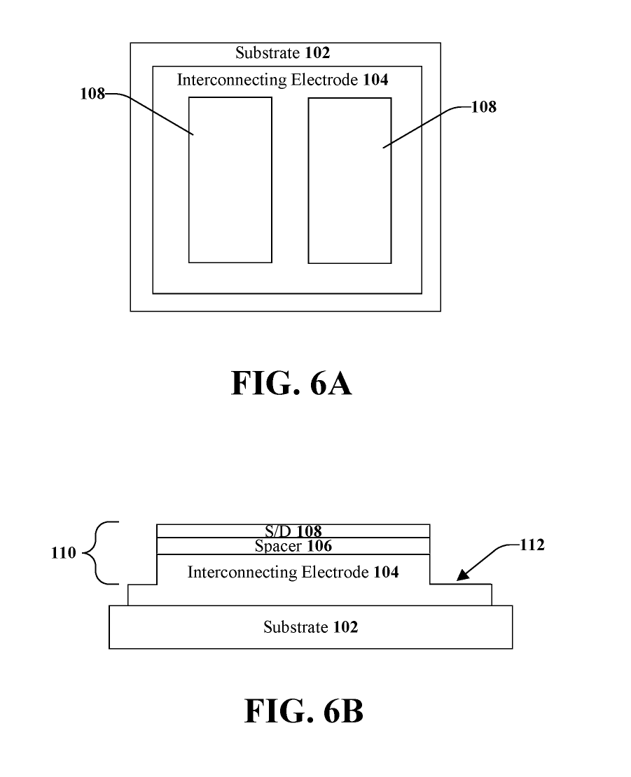

FIG. 6A illustrates a top view of formation of stack structure during fabrication of a vertical bottom-gate thin film transistor in accordance with one or more embodiments described herein. FIG. 6B illustrates a side view of the transistor of FIG. 6A in accordance with one or more embodiments described herein. Repetitive description of like elements employed in other embodiments described herein is omitted for sake of brevity.

After the deposition and patterning of the interconnecting electrode 104 (e.g., FIG. 5A and FIG. 5B), a spacer 106 and the S/D electrode 108 can be deposited. The spacer 106 can be formed as an insulating layer over the interconnecting electrode 104. The spacer 106 can include an isolating material. Further, the S/D electrode 108 can form a second electrode in the transistor.

The S/D electrode 108 can be formed of a conducting material. In an implementation, the interconnecting electrode 104 and the S/D electrode 108 can be formed of the same or similar conducting material. However, in accordance with some implementations the interconnecting electrode 104 and the S/D electrode 108 can be formed of different conducting materials. For example, the interconnecting electrode 104 can be formed of a first conducting material and the S/D electrode 108 can be formed of a second conducting material, different from the first conducting material.

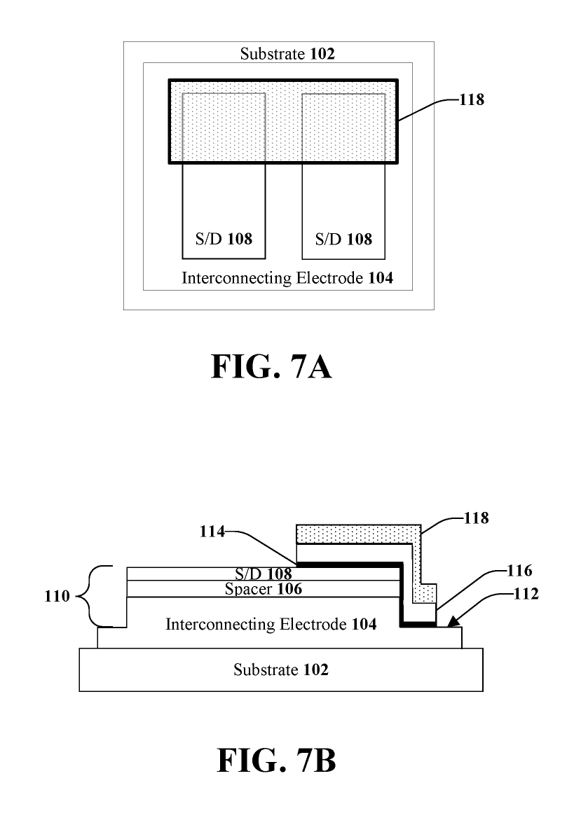

After the spacer 106 and the S/D electrode 108 are deposited, the three layers that include the interconnecting electrode 104, the spacer 106, and the S/D electrode 108 can be patterned to form the stack structure 110. The stack structure can include a vertical step, the extension of which is illustrated at 112. As illustrated in FIG. 6A, a portion of the interconnecting electrode 104 can be used to form the extension illustrated at 112 of the vertical step. Further, as illustrated in FIG. 6B, at this point during the fabrication process the S/D electrode 108 is viewable from the top view of the transistor. It is noted that the view of FIG. 6B and subsequent FIGS. 7B, 8B, and 9B are taken along line C-C′ of FIG. 1.

FIG. 7A illustrates a top view of formation of a gate stack during fabrication of a vertical bottom-gate thin film transistor in accordance with one or more embodiments described herein. FIG. 7B illustrates a side view of the transistor of FIG. 7A in accordance with one or more embodiments described herein. Repetitive description of like elements employed in other embodiments described herein is omitted for sake of brevity.

The stack structure 110 can be capped with an active layer 114, a gate dielectric 116, and a gate electrode layer 118. The gate stack 120 can comprise the gate dielectric 116 and the gate electrode layer 118. The active layer 114 can comprise metal oxide. Multiple junctions can be provided within the active layer 114 adjacent to interfaces between the interconnecting electrode 104, S/D electrode 108, and the active layer 114 (e.g., illustrated by the circled areas in FIG. 2A). Further, the multiple junctions within the active layer can be symmetric. According to some implementations, the gate dielectric 116 can comprise a gate insulator.

In accordance with some implementations, a thermal annealing process can be conducted before the gate electrode layer deposition. According to some implementations, a thermal annealing process can be conducted after the gate electrode layer deposition. The determination of whether to perform the thermal annealing process before or after the gate electrode deposition can be based on the permeable characteristics of the gate film. A subsequent oxidizing heat-treatment can be used to not only form the highly conductive S/D regions but also improve the channel quality by annihilating the native defects.

In an aspect, the annealing can be performed at a temperature greater than 100° C. for a duration between 10 seconds and 10 hours. In another aspect, the temperature at which the TFT can be thermally annealed in an oxidizing ambience can be greater than 300° C. In another aspect, the temperature at which the TFT can be thermally annealed in an oxidizing ambience can be greater than 400° C. In another aspect, the temperature at which the TFT can be thermally annealed in an oxidizing ambience can be greater than 500° C. In another aspect, the temperature at which the TFT can be thermally annealed in an oxidizing ambience can be between 100° C. and 1000° C. In another aspect, the temperature at which the TFT can be thermally annealed in an oxidizing ambience can be between 200° C. and 800° C. In another aspect, the temperature at which the TFT can be thermally annealed in an oxidizing ambience can be between 300° C. and 600° C.

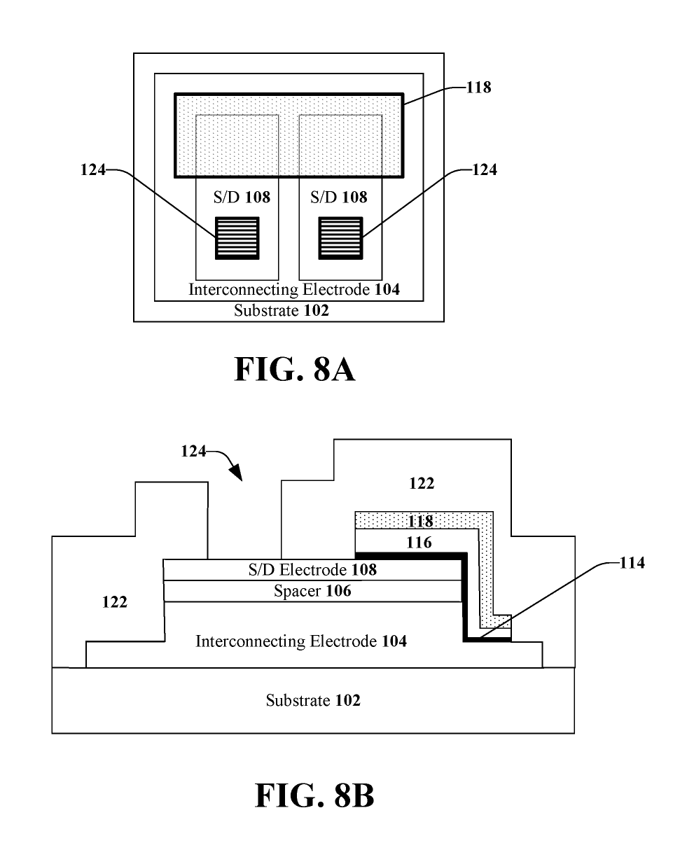

FIG. 8A illustrates a top view of formation of an extra passivation layer and contact holes opening during fabrication of a vertical bottom-gate thin film transistor in accordance with one or more embodiments described herein. FIG. 8B illustrates a side view of the transistor of FIG. 8A in accordance with one or more embodiments described herein. Repetitive description of like elements employed in other embodiments described herein is omitted for sake of brevity.

After patterning of the active layer 114, the gate dielectric 116, and the gate electrode layer 118, a passivation layer 122 (which can be an extra passivation layer) can be introduced to protect the whole device. The passivation layer 122 can serve to protect the source region, the drain region, and the channel region provided within the active layer 114. The introduction of the passivation layer 122 can be followed by contact holes 124 opening. FIG. 8B illustrates a top-view of the transistor after introduction of the passivation layer 122 and formation of the contact holes 124.

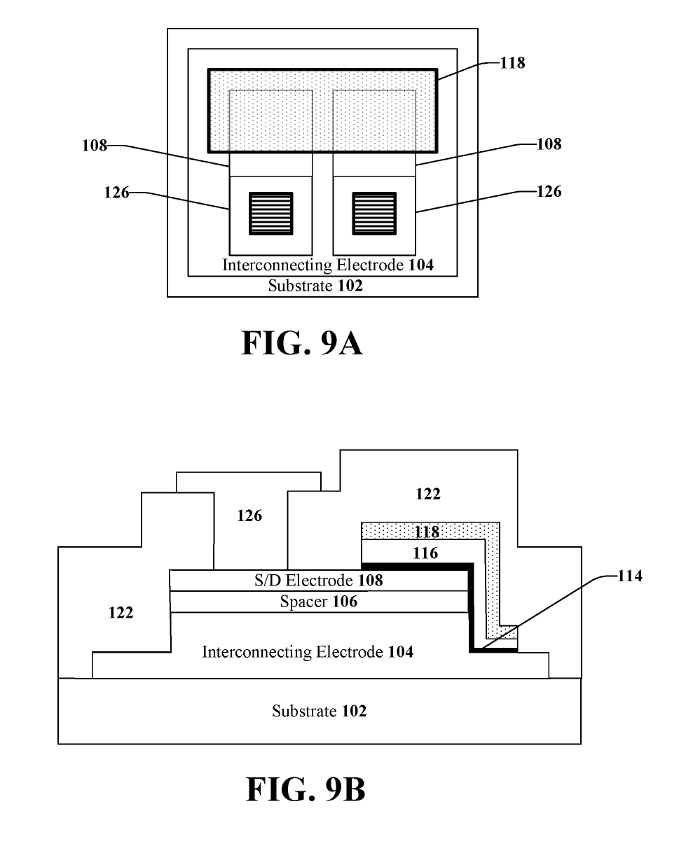

FIG. 9A illustrates a top view of electrode deposition during fabrication of a vertical bottom-gate thin film transistor in accordance with one or more embodiments described herein. FIG. 9B illustrates a side view of the transistor of FIG. 9A in accordance with one or more embodiments described herein. Repetitive description of like elements employed in other embodiments described herein is omitted for sake of brevity.

After formation of the contact holes 124 or openings, metal pads can be formed on the transistor. To form the metal pads, metal electrode deposition can be performed. For example, deposition of the metal electrodes can include depositing the metal pads. According to an implementation, the metal electrode deposition can include forming electrodes over the passivation layer 122 and within the contact holes 124.

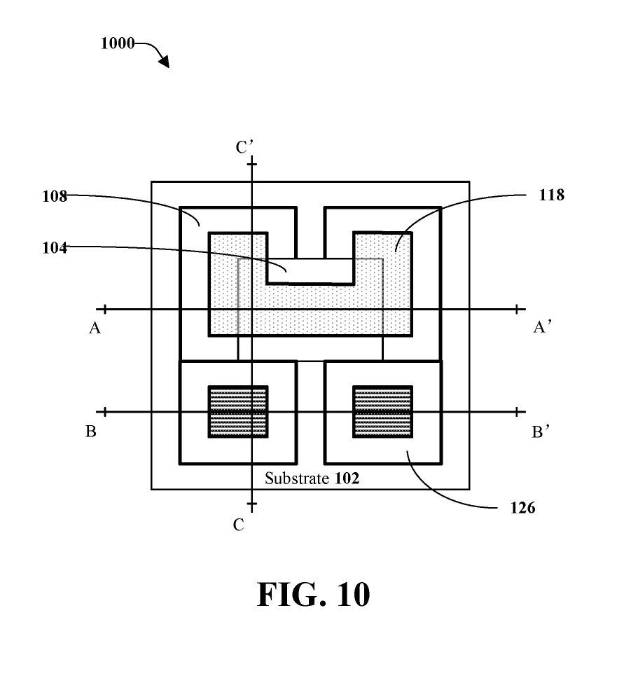

FIG. 10 illustrates another example, non-limiting layout diagram of a vertical TFT with multiple-junction channel in accordance with one or more embodiments described herein. Repetitive description of like elements employed in other embodiments described herein is omitted for sake of brevity.

In this embodiment, the location of the interconnecting electrode and the S/D electrode are changed as compared to the embodiments of FIGS. 1 through 9. As illustrated, the vertical TFT 1000 can include the substrate 102 and the interconnecting electrode 104 formed on the substrate 102.

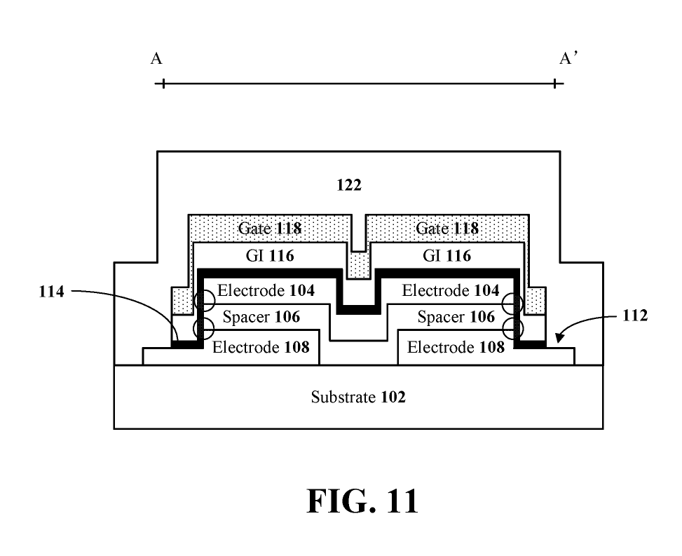

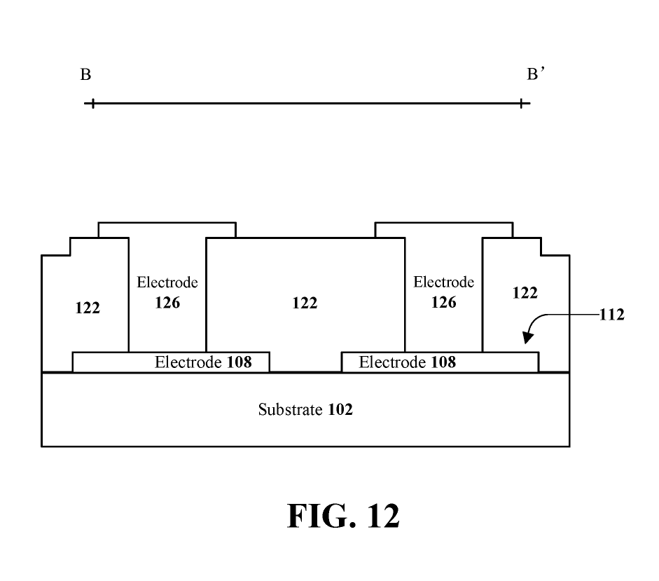

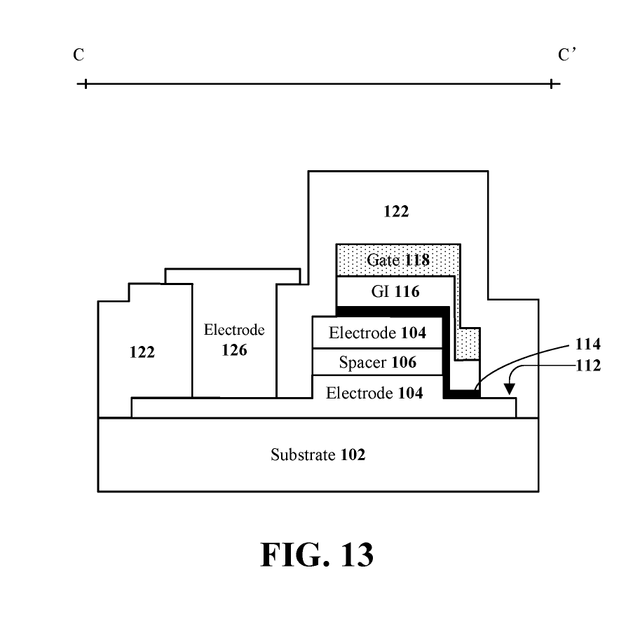

Reference is also made to FIG. 11, which illustrates the layout of the vertical thin-film transistor 1000 along line A-A′ of FIG. 11 in accordance with one or more embodiments described herein. With reference also to FIG. 12, which illustrates the layout of the vertical thin-film transistor 1000 along line B-B′ of FIG. 10 in accordance with one or more embodiments described herein. Reference is also made to FIG. 13, which illustrates the layout of the vertical thin-film transistor 100 along line C-C′ of FIG. 10 in accordance with one or more embodiments described herein. Repetitive description of like elements employed in other embodiments described herein is omitted for sake of brevity.

As illustrated, the S/D electrode 108 can be formed on the substrate 102. The S/D electrode 108 can be patterned. The spacer 106 can be formed on the S/D electrode 108 and a portion of the substrate 102. The interconnecting electrode 104 can be formed on the spacer 106. The interconnecting electrode 104, the spacer 106, and the S/D electrode 108 can be patterned into the stack structure.

The active layer 114 can be formed over and adjacent to the stack structure. As illustrated by the four circled areas in FIG. 11, the multiple-junctions are provided within the active layer adjacent to interfaces between the interconnecting electrode, the source electrode, the drain electrode, and the active layer. The two circled areas on the left are in series with the two circled areas on the right. Further, the current can pass the junction areas denoted on the left of the figure, go through the interconnecting electrode, and pass the junction areas denoted on the right of the figure, for example.

A gate stack can be formed adjacent to the active layer 114. The gate stack can include a gate dielectric 116 formed adjacent to the active layer 114 and a gate electrode layer 118 formed adjacent to the gate dielectric 116. A passivation layer 122 can be formed over and adjacent to the stack structure. Further, contact holes 124 can be formed through the passivation layer 122. Electrodes 126 can be formed over the passivation layer 122 and within the contact holes 124.

In this embodiment, the location of the interconnecting electrode and the S/D electrode are changed as compared to the embodiments of FIGS. 1 through 9. It is noted that in the embodiment of FIGS. 1-9, the electrode for interconnecting multi junctions is deposited before the spacer. However, for the embodiment of FIGS. 10-13, the electrode for interconnecting multi junctions is deposited after the spacer.

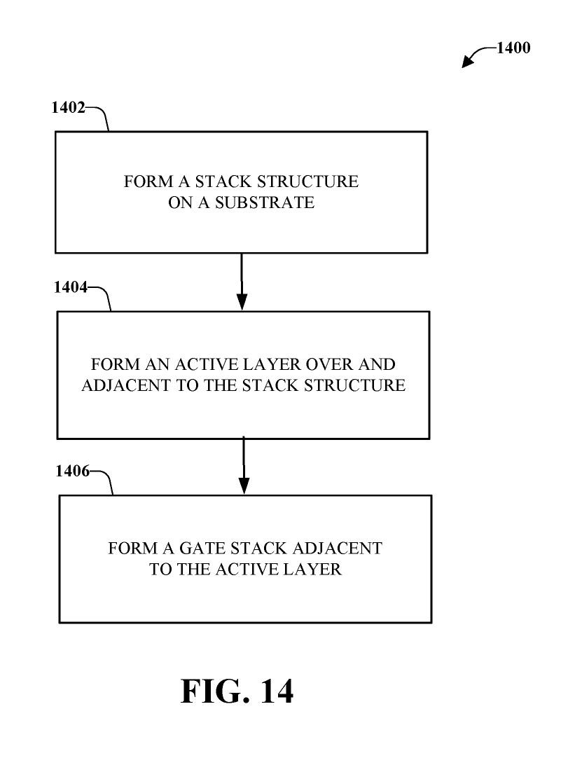

FIG. 14 illustrates an example, non-limiting method 1400 for fabricating a thin film transistor in accordance with one or more embodiments described herein. At 1402, a stack structure can be formed on a substrate. At 1404, an active layer can be formed over and adjacent to the stack structure. The active layer can comprise metal-oxide. At 1406, a gate stack can be formed adjacent to the active layer. The gate stack can include a dielectric and a gate electrode. The stack structure comprises an interconnecting electrode, S/D electrode and a dielectric spacer layer between the interconnecting electrode and the S/D electrode.

According to some implementations, forming the active layer, at 1404, and forming the gate stack, at 1406, can include using one mask for the active layer and the gate stack. According to some implementations, forming the active layer, at 1404, and forming the gate stack, at 1406, can include patterning the active layer and the gate stack. Further to this implementation, patterning the active layer and the gate stack can include performing a single photolithography step. Accordingly, at least one fabrication step can be eliminated in accordance with the disclosed aspects.

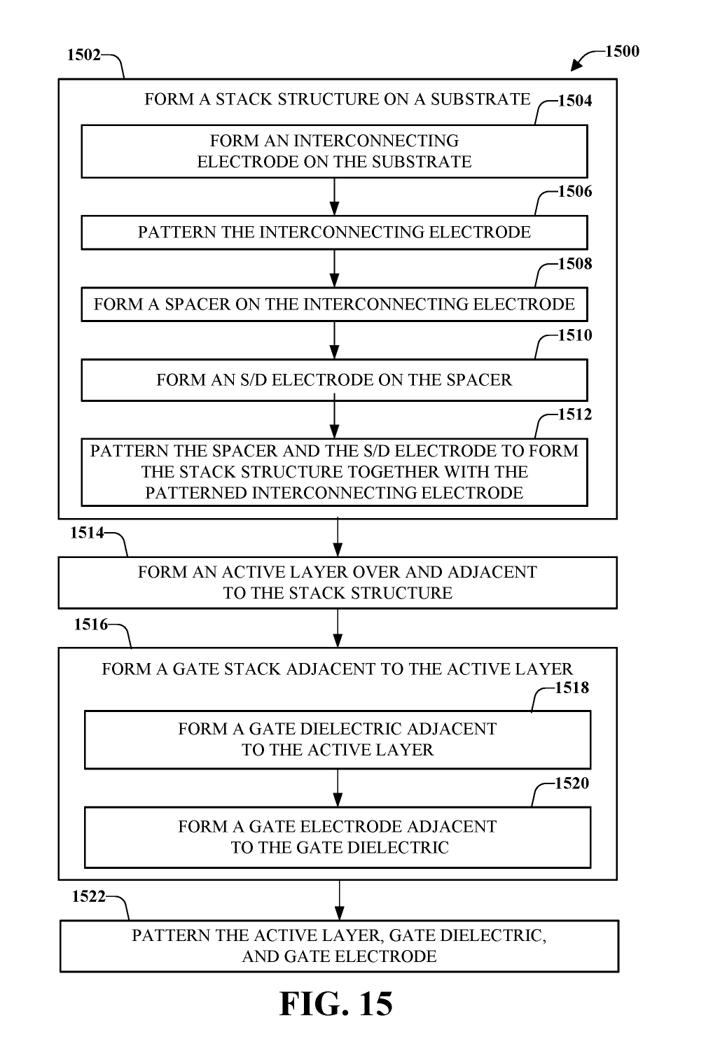

FIG. 15 illustrates an example, non-limiting method 1500 for forming a vertical thin-film transistor with multiple-junction channel in accordance with one or more embodiments described herein. FIG. 15 can be utilized to form the vertical TFT of FIGS. 1-9. At 1502, a stack structure can be formed on a substrate. Forming the stack structure can include forming an interconnecting electrode layer on the substrate, at 1504. At 1506, the interconnecting electrode can patterned. At 1508, a spacer can be formed on the interconnecting electrode. At 1510, an S/D electrode can be formed on the spacer. According to some implementations, the spacer can be an insulating layer located between the bottom electrode layer and the upper electrode layer. Further, at 1512, the spacer and the S/D electrode can be patterned into the stack structure together with the patterned interconnecting electrode.

According to some implementations, the interconnecting electrode and/or the S/D layer can be formed of conducting material. In an aspect, the interconnecting electrode and the S/D electrode can be formed of the same or a similar conducting material. According to other aspects, the interconnecting electrode and the S/D electrode can be formed of different conducting materials. Multiple junctions can be provided within the active layer adjacent to interfaces between the interconnecting electrode, S/D electrode, and the active layer (e.g., illustrated by the four circled areas in FIG. 11). Further, the multiple junctions within the active layer can be symmetric.

At 1514, an active layer can be formed over and adjacent to the stack structure. According to an implementation, the active layer comprises metal oxide. Further, at 1516, a gate stack can be formed adjacent to the active layer. According to an implementation, forming the gate stack can include forming a gate dielectric adjacent to the active layer, at 1518. Further, to form the gate stack, at 1520, a gate electrode can be formed adjacent to the gate dielectric. At 1522, the active layer, the gate dielectric, and the gate electrode can be patterned.

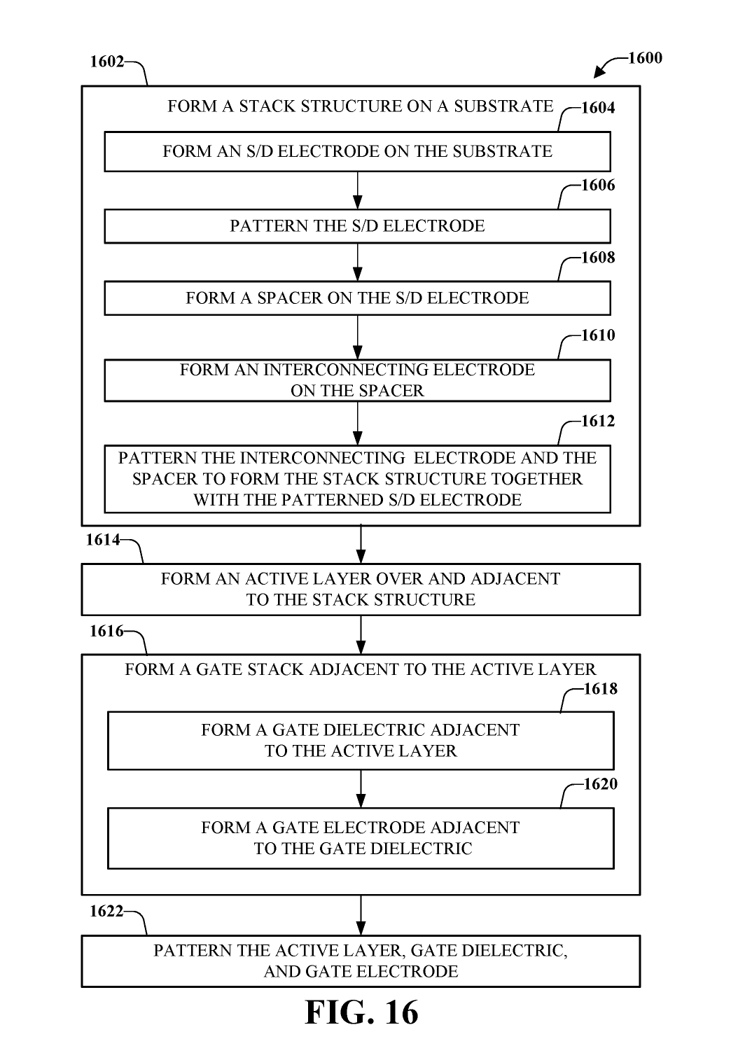

FIG. 16 illustrates an example, non-limiting method 1600 for forming another vertical thin-film transistor with multiple-junction channel in accordance with one or more embodiments described herein. FIG. 16 can be utilized to form the vertical TFT of FIGS. 10-13.

The method 1600 begins, at 1602 when a stack structure is formed on a substrate. Forming the stack structure can include forming an S/D electrode on a substrate, at 1604. The S/D electrode can be patterned, at 1606. A spacer can be formed on the S/D electrode, at 1608. The spacer can also be formed on a portion of the substrate. At 1610, an interconnecting electrode can be formed on the spacer. Further, at 1612, the interconnecting electrode and the spacer can be patterned to form the stack structure together with the patterned S/D electrode.

An active layer can be formed over and adjacent to the stack structure, at 1614. According to an implementation, the active layer comprises metal oxide. Further, at 1616, a gate stack can be formed adjacent to the active layer. According to an implementation, forming the gate stack can include forming a gate dielectric adjacent to the active layer, at 1618. Further, to form the gate stack, at 1620, a gate electrode can be formed adjacent to the gate dielectric. At 1622, the active layer, the gate dielectric, and the gate electrode can be patterned.

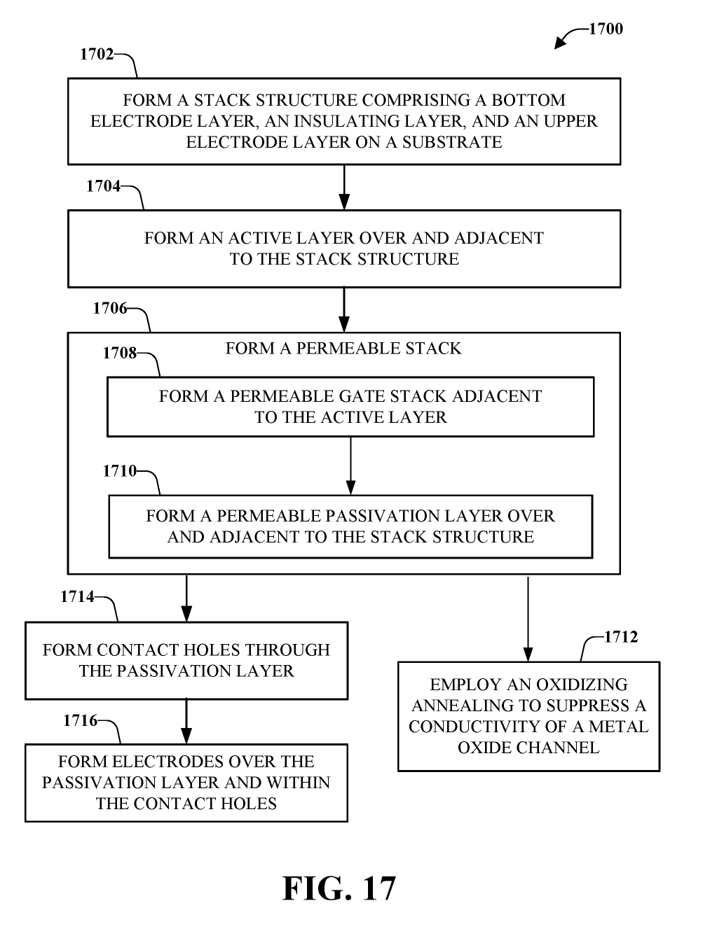

FIG. 17 illustrates an example, non-limiting method 1700 for fabricating a vertical thin film transistor in accordance with one or more embodiments described herein. At 1702, a stack structure comprising a bottom electrode layer, an insulating layer, and an upper electrode layer can be formed on a substrate. At 1704, an active layer can be formed over and adjacent to the stack structure. The active layer can comprise metal oxide.

At 1706 a permeable stack can be formed. Forming the permeable stack can include forming a permeable gate stack adjacent to the active layer, at 1708. Further, at 1710, a permeable passivation layer can be formed over and adjacent to the stack structure. The permeable layer can include at least one of silicon oxide, silicon oxynitride, aluminum-zinc oxide, indium-zinc oxide, or indium-tin oxide. The permeable layer can be a gas permeable layer and the gate stack can be a gas permeable gate stack. In an implementation, at 1712, the method 1700 can include employing an oxidizing annealing to suppress a conductivity of a metal oxide channel. Since the gate stack can include gas permeable layers, the conductivity of the MO channel can be further suppressed by the thermal oxidization, thus lowering the off-state current.

Further, in an additional or alternative implementation, the method 1700 can include forming contact holes through the passivation layer, at 1714. Further, at 1716, electrodes can be formed over the passivation layer and within the contact holes.

For simplicity of explanation, the computer-implemented methodologies are depicted and described as a series of acts. It is to be understood and appreciated that the subject innovation is not limited by the acts illustrated and/or by the order of acts, for example acts can occur in various orders and/or concurrently, and with other acts not presented and described herein. Furthermore, not all illustrated acts can be required to implement the computer-implemented methodologies in accordance with the disclosed subject matter. In addition, those skilled in the art will understand and appreciate that the computer-implemented methodologies could alternatively be represented as a series of interrelated states via a state diagram or events. Additionally, it should be further appreciated that the computer-implemented methodologies disclosed hereinafter and throughout this specification are capable of being stored on an article of manufacture to facilitate transporting and transferring such computer-implemented methodologies to computers. The term article of manufacture, as used herein, is intended to encompass a computer program accessible from any computer-readable device or storage media.

What has been described above includes examples of the subject innovation. It is, of course, not possible to describe every conceivable combination of components or methods for purposes of describing the subject innovation, but one of ordinary skill in the art may recognize that many further combinations and permutations of the subject innovation are possible. Accordingly, the subject innovation is intended to embrace all such alterations, modifications, and variations that fall within the spirit and scope of the appended claims. Furthermore, to the extent that the term “includes” and “involves” are used in either the detailed description or the claims, such terms are intended to be inclusive in a manner similar to the term “comprising” as “comprising” is interpreted when employed as a transitional word in a claim.

Reference throughout this specification to “one embodiment,” or “an embodiment,” means that a particular feature, structure, or characteristic described in connection with the embodiment is included in at least one embodiment. Thus, the appearances of the phrase “in one embodiment,” or “in an embodiment,” in various places throughout this specification are not necessarily all referring to the same embodiment. Furthermore, the particular features, structures, or characteristics may be combined in any suitable manner in one or more embodiments.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive—in a manner similar to the term “comprising” as an open transition word—without precluding any additional or other elements.

1. A transistor structure, comprising:
a layered stack structure formed on a substrate, wherein the layered stack structure comprises an interconnecting electrode, a source electrode, and a drain electrode;
an active layer comprising metal-oxide formed over and adjacent to the layered stack structure;
a gate stack adjacent to the active layer, the gate stack comprising a gate dielectric adjacent to the active layer and a gate electrode adjacent to the gate dielectric; and
a multiple-junction channel region provided within the active layer adjacent to the gate stack, the multiple-junction channel region comprises multiple junctions connected in series.

2. The transistor structure of claim 1, wherein the layered stack structure further comprises a spacer, and wherein:
the interconnecting electrode is deposited on the substrate;
the spacer is deposited on the interconnecting electrode; and
the source electrode and the drain electrode are deposited on the spacer, and wherein the multiple-junction channel region is provided within the active layer adjacent to interfaces between the interconnecting electrode, the source electrode, the drain electrode, and the active layer.

3. The transistor structure of claim 1, wherein the layered stack structure further comprises a spacer, and wherein:
the source electrode and the drain electrode are deposited on the substrate;
the spacer is deposited on the source electrode and the drain electrode; and
the interconnecting electrode is deposited on the spacer, and wherein the multiple-junction channel region is provided within the active layer adjacent to interfaces between the interconnecting electrode, the source electrode, the drain electrode, and the active layer.

4. The transistor structure of claim 1, wherein the gate stack comprises a gas permeable layer.

5. The transistor structure of claim 4, wherein the gas permeable layer comprises at least one of: silicon oxide, silicon oxynitride, aluminum-zinc oxide, indium-zinc oxide, or indium-tin oxide.

6. (canceled)

7. The transistor structure of claim 1, further comprising:
a passivation layer formed over and adjacent to the layered stack structure;
contact holes formed within the passivation layer; and
electrodes formed over the passivation layer and within the contact holes.

8.-15. (canceled)

16. A vertical transistor, comprising:
a substrate;
a source electrode and a drain electrode separated from a series interconnecting electrode by a spacer, the source electrode and the drain electrode are formed over the substrate;
a metal oxide active layer formed over the series interconnecting electrode, the source electrode, and the drain electrode, and adjacent to the source electrode, the drain electrode, the spacer, and the series interconnecting electrode;
a gate stack adjacent to the metal oxide active layer; and
a multiple-junction channel region provided within the metal oxide active layer adjacent to the gate stack, wherein the series interconnecting electrode connects junctions of the multiple-junction channel in series.

17. The vertical transistor of claim 16, wherein the gate stack comprises:
a gate dielectric adjacent to the metal oxide active layer; and
a gate electrode adjacent to the gate dielectric.

18. The vertical transistor of claim 16, wherein the metal oxide active layer is patterned with the gate stack.

19. The vertical transistor of claim 16, wherein the gate stack comprises a gas permeable layer.

20. The vertical transistor of claim 19, wherein the gas permeable layer comprises at least one of: silicon oxide, silicon oxynitride, aluminum-zinc oxide, indium-zinc oxide, and indium-tin oxide.

21. The transistor structure of claim 1, wherein a first junction and a second junction of the multiple-junction channel region are symmetric.

22. The transistor structure of claim 21, further comprising a source junction and a drain junction, wherein the source junction and the drain junction are symmetric.

23. The transistor structure of claim 1, further comprising a source and a drain located on a same plane.

24. A transistor device, comprising:
a layered stack structure formed on a substrate, the layered stack comprising an interconnecting electrode, a spacer, a source electrode, and a drain electrode;
an active layer comprising metal-oxide formed over and adjacent to the layered stack structure;
a gate stack adjacent to the active layer, the gate stack comprising a gate dielectric adjacent to the active layer and a gate electrode adjacent to the gate dielectric; and
a multiple-junction channel region provided within the active layer adjacent to the gate stack, the multiple-junction channel region comprises multiple junctions connected in series.

25. The transistor device of claim 24, wherein
the interconnecting electrode is deposited on the substrate,
the spacer is deposited on the interconnecting electrode; and
the source electrode and the drain electrode are deposited on the spacer, wherein the multiple-junction channel region is provided within the active layer adjacent to interfaces between the interconnecting electrode, the source electrode, the drain electrode, and the active layer.

26. The transistor device of claim 24, wherein
the source electrode and the drain electrode are deposited on the substrate;
the spacer is deposited on the source electrode and the drain electrode; and
the interconnecting electrode is deposited on the spacer, wherein the multiple-junction channel region is provided within the active layer adjacent to interfaces between the interconnecting electrode, the source electrode, the drain electrode, and the active layer.

27. The transistor device of claim 24, wherein the gate stack comprises a gas permeable layer.

28. The transistor device of claim 24, wherein the gas permeable layer comprises at least one of: silicon oxide, silicon oxynitride, aluminum-zinc oxide, indium-zinc oxide, or indium-tin oxide.

29. The transistor device of claim 24, further comprising:
a passivation layer formed over and adjacent to the layered stack structure;
contact holes formed within the passivation layer; and
electrodes formed over the passivation layer and within the contact holes.
